(19) United States
(12) Patent Application Publication
(10) Pub. No.: US 2025/0185324 A1
(43) Pub. Date: Jun. 5, 2025

(54) SEMICONDUCTOR DEVICE, METHOD FOR MANUFACTURING SEMICONDUCTOR DEVICE, AND ELECTRIC POWER CONVERTER

(71) Applicant: Minebea Power Semiconductor Device Inc., Ibaraki (JP)

(72) Inventor: Masaki SHIRAISHI, Hitachi-shi (JP)

(21) Appl. No.: 18/843,734

(22) PCT Filed: Dec. 9, 2022
(86) PCT No.: PCT/JP2022/045441

§ 371 Date: Sep. 4, 2024

(30) Foreign Application Priority Data
Mar. 28, 2022 (JP) 2022-051429

(51) Int. Cl. H10D 62/60; H02M 7/00; H10D 12/00; H10D 12/01; H10D 62/10; H10D 84/00

(52) U.S. Cl. CPC H10D 62/605; H02M 7/003; H10D 12/021; H10D 12/038; H10D 12/212; H10D 12/481; H10D 62/105; H10D 84/161

(57) ABSTRACT

To provide a semiconductor device, a method for manufacturing a semiconductor device, and an electric power converter realizing prevention of rise of on-voltage in an IGBT and improvement of a reverse recovery characteristic of a diode part by a simpler process. In the semiconductor device 100 (RC-IGBT), in the RC-IGBT having an IGBT part and a diode part in a single chip, a body layer 11 of the diode part is formed shallower than a body layer 10 of the IGBT part, a lifetime control layer 8 of the IGBT part is formed in the body layer 10 of the IGBT part, and the lifetime control layer 8 of the diode part is formed in a drift layer 4 below the body layer 11 of the diode part.

### TECHNICAL FIELD

This invention relates to a semiconductor device, a method for manufacturing the semiconductor device, and an electric power converter.

### BACKGROUND ART

A reverse conducting IGBT (hereinafter, called “RC-IGBT”) having an IGBT (Insulated Gate Bipolar Transistor) and a diode in the same chip has advantages such as (1) chip downsizing by commonly using a termination region of the IGBT and the diode, and (2) reduction in thermal resistance since a loss which occurs in an IGBT region or a diode region is dissipated in the entire chip. On the other hand, since an IGBT and a diode are formed in the same chip, it is difficult to simultaneously optimize chips. Particularly, it is difficult to control the lifetime of the diode part. There are challenges to lower implantation in the diode and reduction in recovery loss.

As means for lowering implantation in the diode part in the RC-IGBT, for example, patent literature 1 discloses a semiconductor device in which a lifetime control region 150 is formed in a drift layer 104 over an IGBT region 11 and a diode region 12. According to the patent literature 1, by providing a lifetime control region in an n-drift layer below a p-body layer in the LGBT part and the diode part, the reverse recovery characteristic of the diode part can be improved.

Patent Literature 2 discloses a semiconductor device in which a lifetime control region 52 is formed within a drift region 27 in a diode range 40 in an RC-IGBT. In Patent Literature 2, by providing the lifetime control region 52 only in an n-drift layer below a p-body layer in the diode range 40, without sacrificing the characteristic of the IGBT, the reverse recovery characteristic of the diode part can be improved.

### CITATION LIST

### Patent Literature

Patent Literature 1: Japanese Unexamined Patent Application Publication No. 2015-144232
Patent Literature 2: Japanese Unexamined Patent Application Publication No. 2017-59725

### SUMMARY OF INVENTION

### Technical Problem

In the patent literature 1, however, since the lifetime control layer is provided in the n-drift layer below the p-body layer not only in the diode part but also in the IGBT part, there is a problem that on-voltage of the IGBT rises.

In the patent literature 2, since the lifetime control layer is provided only in the n-drift layer below the p-body layer in the diode layer, the reverse recovery characteristic of the diode can be improved without sacrificing the on-voltage characteristic of the IGBT. However, to provide the lifetime control layer formed by irradiation of light ion (for example, proton or helium) only in the diode part, a metal mask has to be placed so that the IGBT part is not irradiated with light ions. There is a problem that the difficulty level of the process increases.

In consideration of the above circumstances, an object of the present invention is to provide a semiconductor device, a method for manufacturing a semiconductor device, and an electric power converter realizing prevention of rise of on-voltage in an IGBT and improvement of a reverse recovery characteristic of a diode part by a simpler process.

### Solution to Problem

In order to solve the above problems, according to a first aspect of the present invention, there is provided a semiconductor device as an RC-IGBT having an IGBT part and a diode part in a single chip. In the semiconductor device, a body layer of the diode part is formed shallower than a body layer of the IGBT part, a lifetime control layer of the IGBT part is formed in the body layer of the IGBT part, and the lifetime control layer of the diode part is formed in a drift layer below the body layer of the diode part.

In order to solve the above problems, according to a second aspect of the present invention, there is provided a method for manufacturing the above described semiconductor device of the present invention, in which the body layer of the IGBT part and the body layer of the diode part are formed in different steps.

In order to solve the above problems, according to another aspect of the present invention, there is provided an electric power converter comprising: a pair of DC terminals; AC terminals of the number which is equal to the number of phases of AC output; switching legs of the number which is equal to the number of phases of AC output, the switching legs being connected between the pair of DC terminals and each being made by connecting, in series, two parallel circuits each configured by a switching element and a diode connected to the switching element in inverse-parallel; and a gate circuit controlling the switching element. In the electric power converter, the diode and the switching element are the above described semiconductor device.

More specific configurations of the present invention are described in Claims.

### Advantageous Effects of Invention

According to the present invention, it is possible to provide a semiconductor device, a method for manufacturing a semiconductor device, and an electric power converter realizing prevention of rise of on-voltage in an IGBT and improvement of a reverse recovery characteristic of a diode part by a simpler process.

Objects, configurations, and effects other than the above will be apparent from the description of the following embodiments.

### BRIEF DESCRIPTION OF DRAWINGS

FIG. 1 is a schematic cross section illustrating an example of a semiconductor device of the present invention.

FIG. 2(a) is a schematic cross section illustrating a step in a method for manufacturing a semiconductor device of the present invention.

FIG. 2(b) is a schematic cross section illustrating a step in the method for manufacturing the semiconductor device of the present invention.

FIG. 2(c) is a schematic cross section illustrating a step in the method for manufacturing the semiconductor device of the present invention.

FIG. 2(d) is a schematic cross section illustrating a step in the method for manufacturing the semiconductor device of the present invention.

FIG. 2(e) is a schematic cross section illustrating a step in the method for manufacturing the semiconductor device of the present invention.

FIG. 2(f) is a schematic cross section illustrating a step in the method for manufacturing the semiconductor device of the present invention.

FIG. 3 is a circuit diagram illustrating a schematic configuration of an example of an electric power converter of the invention.

### DESCRIPTION OF EMBODIMENTS

Hereinafter, the present invention will be described in detail with reference to the drawings.

### [Semiconductor Device]

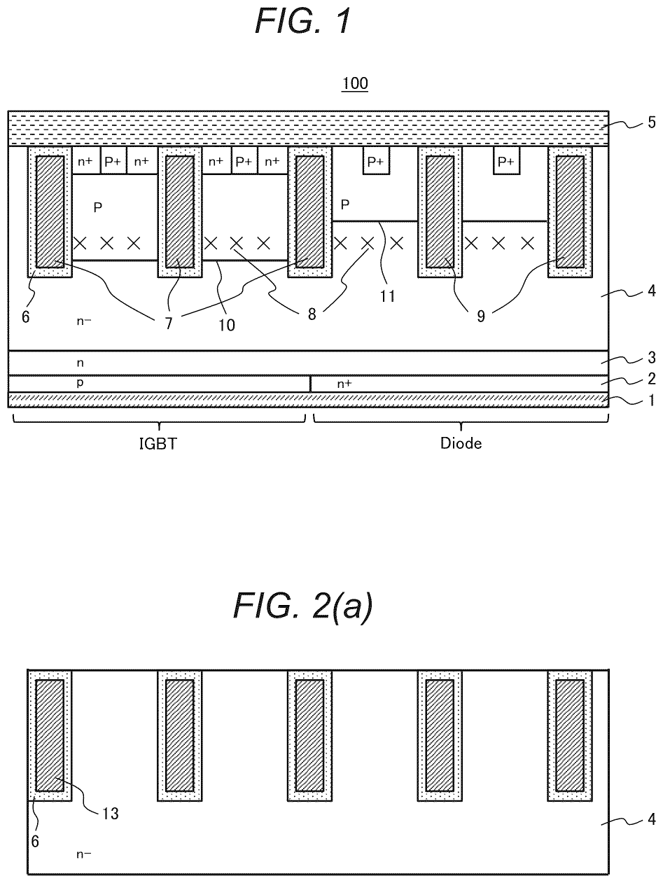

FIG. 1 is a schematic cross section illustrating an example of a semiconductor device of the present invention. As illustrated in FIG. 1, a semiconductor device (RC-IGBT) 100 of the present invention has an IGBT part and a diode part. It has a structure in which, from the rear face side toward the surface side, a collector electrode layer/cathode electrode layer 1, a diffusion layer 2, a buffer layer 3, an n-drift layer 4, p-body layers 10 and 11, and an emitter electrode/anode electrode 5 are stacked. The conduction types “p” and “n” in FIG. 1 may be reversed.

In the surface structure, the IGBT part has the p-body layer 10 sandwiched by trenches. An n+ source layer, and a p+ layer for connecting the p-body layer 10 and the emitter electrode 5 are formed in the surface. The diode part has the p-body layer 11 sandwiched by trenches. A p+ layer for connecting the p-body layer 11 and the anode electrode 5 is provided in the surface.

The characteristics of the semiconductor device 100 illustrated in FIG. 1 are that the p-body layer 10 in the IGBT part is formed deeper than the p-body layer 11 in the diode part, and the lifetime control layer 8 is formed in the p-body layer 10 in the IGBT part, and formed within the n-drift layer 4 below the p-body layer 11 in the diode part. In the diode part, since the lifetime control layer 8 is provided in the n-drift layer 4, carriers in the n-drift layer 4 disappear efficiently in the lifetime control layer 8 during reverse recovery. Consequently, the reverse recovery characteristic can be improved. On the other hand, in the IGBT part, since the lifetime control layer 8 is provided in the p-body layer 10, low on-voltage can be realized without dissipation of carriers in the n-drift layer 4 in the lifetime control layer 8 during the conduction time of the IGBT. That is, by making the depth of the p-body layer in the IGBT part and that in the diode part different, despite that the lifetime control layer 8 having the same depth is provided, the reverse recovery characteristic of the diode can be improved without imparting the low on-voltage characteristic of the IGBT.

### [Method for Manufacturing Semiconductor Device]

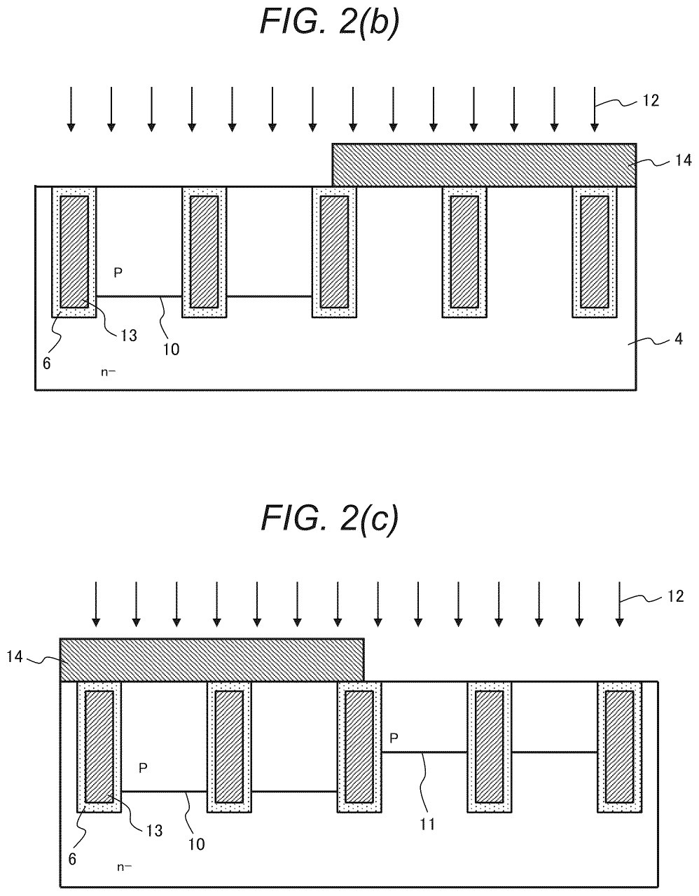

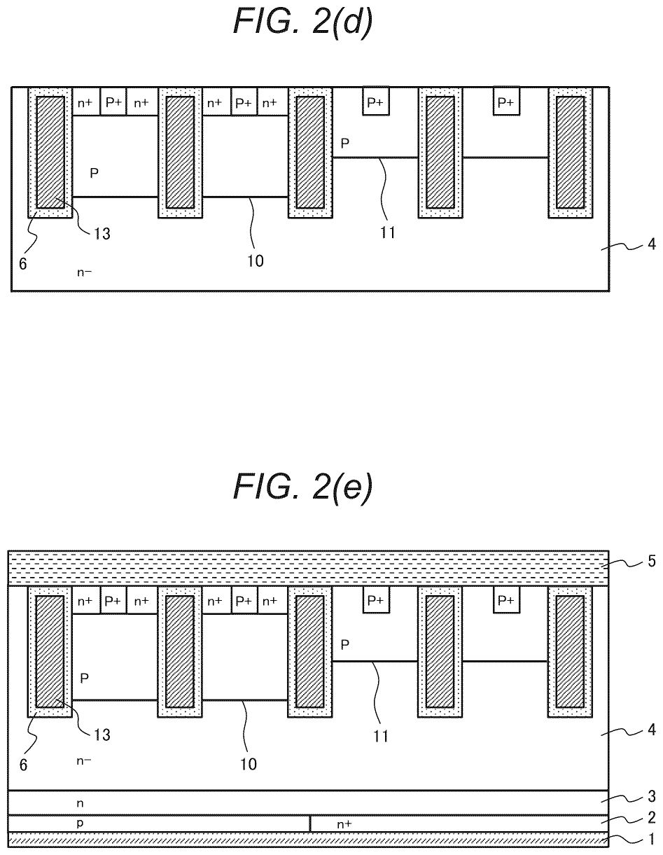

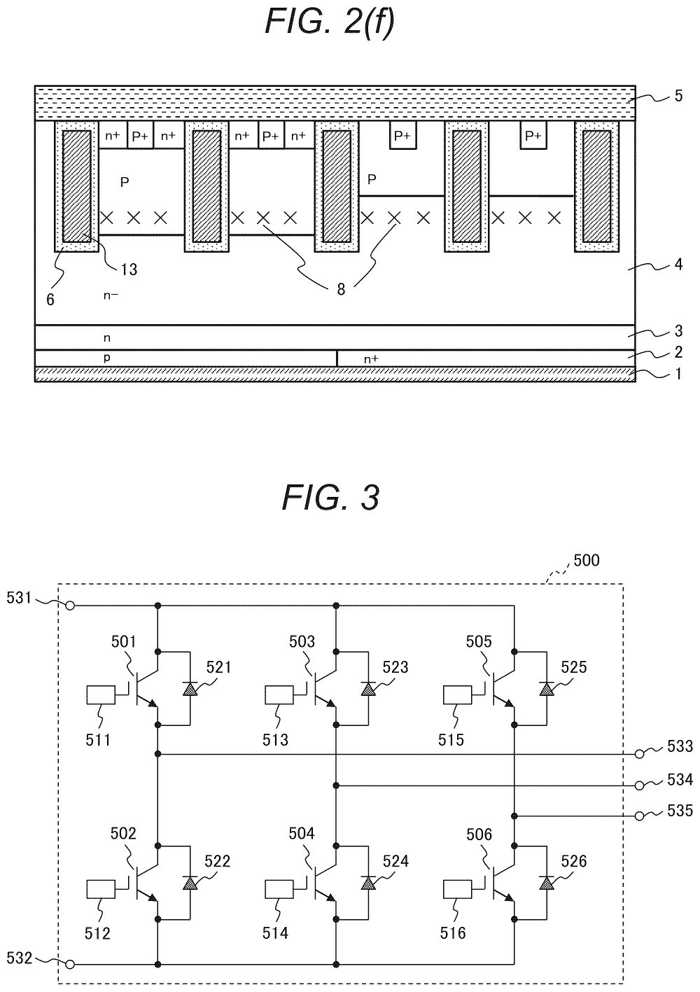

FIGS. 2(a) to 2(f) are schematic cross sections illustrating steps of a method for manufacturing a semiconductor device of the present invention. With reference to FIGS. 2(a) to 2(f), the method for manufacturing a semiconductor device of the present invention will be described.

First, as illustrated in FIG. 2(a), trenches in each of which a polysilicon electrode 13 is buried in the n-drift layer 4 via an oxide film 6 are formed in the IGBT part and the diode part. The polysilicon electrode 13 corresponds to a gate 7 or a gate/emitter 9 in FIG. 1.

Subsequently, as illustrated in FIG. 2(b), by irradiating the IGBT part with ions 12 to diffuse light ions, the p-body layer 10 is formed. At this time, a photoresist 14 is mounted so that the diode part is not irradiated with the ions 12.

Subsequently, as illustrated in FIG. 2(c), by irradiating the diode part with the ions for diffusion, the p-body layer 11 is formed. At this time, the photoresist 14 is mounted so that the IGBT part is not irradiated with the ions 12. To make the p-body layer 11 in the diode part shallower than the p-body layer 10 in the IGBT part, at the time of formation of the p-body layer 11 in the diode part, the depth of implantation of the ions 12 is made shallower as compared with that in the IGBT part, the diffusion temperature is lowered in a diffusion process, or diffusion time is shortened.

Subsequently, as illustrated in FIG. 2(d), n+ layers and p+ layers are formed in the p-body layer 10 in the IGBT part, and P+ layers are formed in the p-body layer 11 in the diode part.

Subsequently, as illustrated in FIG. 2(e), the emitter electrode/anode electrode 5 in the surface is formed, the n-buffer layer 3 is formed in the rear face, a p layer is formed in the IGBT part and an n+ layer is formed in the diode part as the diffusion layer 2, and the collector electrode layer/cathode electrode layer 1 in the rear face is formed.

Finally, as illustrated in FIG. 2(f), the lifetime control layer 8 is formed in the p-body layer 10 in the IGBT part and in the n-drift layer 4 below the p-body layer 11 in the diode part. The lifetime control layer can be formed, for example, by irradiating a desired position with light ions such as proton or helium. In the light ion irradiation, the irradiation depth in the IGBT part and that in the diode part are the same. Consequently, irradiation can be performed without blocking light ions by a metal mask or the like.

As described above, according to the method for manufacturing the semiconductor device of the present invention, by making formation of the p-body layer 10 in the IGBT part and formation of the p-body layer 11 in the diode part performed in different steps, the body layer in the IGBT part and that in the diode part can be formed at different depths.

### [Electric Power Converter]

FIG. 3 is a circuit diagram illustrating a schematic configuration of an example of an electric power converter of the present invention. FIG. 3 illustrates an example of the circuit configuration of an electric power converter 500 of the embodiment and the relation of connection between a DC power supply and a three-phase AC motor (AC load).

In the electric power converter 500 of the embodiment, the semiconductor device of the present invention is used as elements 501 to 506 and 521 to 526.

As illustrated in FIG. 3, the electric power converter 500 of the embodiment has a P terminal 531 and an N terminal 532 as a pair of DC terminals, and a U terminal 533, a V terminal 534, and a W terminal 535 as AC terminals of the same number as the phase number of AC outputs.

A switching leg is provided which is made by series connection of a pair of power switching elements 501 and 502, and whose output is the U terminal 533 connected to the point of the series connection. A switching leg having the same configuration is also provided which is made by series connection of the power switching elements 503 and 504, and whose output is the V terminal 534 connected to the point of the series connection. A switching leg having the same configuration is also provided which is made by series connection of the power switching elements 505 and 506, and whose output is the W terminal 535 connected to the point of the series connection.

The switching legs of three phases made by the power switching elements 501 to 506 are connected between DC terminals of the P terminal 531 and the N terminal 532, and DC power is supplied from a not-illustrated DC power supply. The U terminal 533, the V terminal 534, and the W terminal 535 as AC terminals of three phases of the electric power converter 500 are connected as a three-phase AC power supply to a not-illustrated three-phase AC motor.

The diodes 521 to 526 are inverse-parallel connected to the power switching elements 501 to 506, respectively. For example, gate circuits 511 to 516 are connected to input terminals of gates of the power switching elements 501 to 506 made by IGBTs, respectively, and the power switching elements 501 to 506 are controlled by the gate circuits 511 to 516, respectively. The gate circuits 511 to 516 are generally controlled by an overall control circuit (not illustrated).

The power switching elements 501 to 506 are generally properly controlled by the gate circuits 511 to 516 to convert the DC power of a DC power supply Vcc to three-phase AC power, and the three-phase AC power is output from the U terminal 533, the V terminal 534, and the W terminal 535.

By applying the semiconductor device (RC-IGBT) of the present invention to the electric power converter 500, the power switching elements 501 to 506 and the diodes 521 to 526 can be integrated as one device. Consequently, miniaturization of the device can be achieved. As described above, by using the semiconductor device of the present invention, an electric power converter with improved recovery characteristic of the diode part can be provided.

As described above, the present invention can provide the semiconductor device, the method for manufacturing the semiconductor device, and the electric power converter realizing prevention of rise in on-voltage of an IGBT and improvement in the reverse recovery characteristic of the diode part by simpler process.

The present invention is not limited to the above-described embodiments, and further includes various modifications. For example, the above-described embodiments have been described in detail in order to facilitate the understanding of the present invention, and the present invention is not necessarily limited to those including all of the described configurations.

### LIST OF REFERENCE SIGNS

1 . . . collector electrode layer/cathode electrode layer, 2 . . . diffusion layer, 3 . . . buffer layer, 4 . . . n-drift layer, 5 . . . emitter electrode/anode electrode, 6 . . . oxide film, 7 . . . gate, 8 . . . lifetime control layer, 9 . . . gate/emitter, 10 . . . p-body layer in IGBT part, 11 . . . p-body layer in diode part, 12 . . . ion, 13 . . . polysilicon electrode, 14 . . . photoresist, 100 . . . semiconductor device, 500 . . . electric power converter, 501 to 506 . . . power switching elements, 511 to 516 . . . gate circuits, 521 to 526 . . . diodes, 531 . . . P terminal, 532 . . . N terminal, 533 . . . U terminal, 534 . . . V terminal, 535 . . . W terminal

1. A semiconductor device as an RC-IGBT having an IGBT part and a diode part in a single chip, wherein
a body layer of the diode part is formed shallower than a body layer of the IGBT part,
a lifetime control layer of the IGBT part is formed in the body layer of the IGBT part, and
the lifetime control layer of the diode part is formed in a drift layer below the body layer of the diode part.

2. The semiconductor device according to claim 1, wherein
the lifetime control layer of the IGBT part and the lifetime control layer of the diode part are formed at the same depth.

3. The semiconductor device according to claim 1, wherein
the lifetime control layer is made of light ion.

4. A method for manufacturing the semiconductor device according to claim 1, wherein
the body layer of the IGBT part and the body layer of the diode part are formed in different steps.

5. An electric power converter comprising:
a pair of DC terminals;
AC terminals of the number which is equal to the number of phases of AC output;
switching legs of the number which is equal to the number of phases of AC output, the switching legs being connected between the pair of DC terminals, and the switching leg including two parallel circuits connected in series, and each of the two parallel circuits being formed of a switching element and a diode connected reversely in parallel to the switching element; and
a gate circuit controlling the switching element, wherein
the diode and the switching element are the semiconductor device according to claim 1.
